(19) United States
(12) Patent Application Publication
(10) Pub. No.: US 2013/0068293 A1
(43) Pub. Date: Mar. 21, 2013

(54) SUBSTRATE GEOMETRY FOR THREE DIMENSIONAL PHOTOVOLTAICS FABRICATION

(71) Applicant: NATIONAL INSTITUTE OF STANDARDS AND TECHNOLOGY, Gaithersburg, MD (US)

(72) Inventors: Daniel Josell, North Potomac, MD (US); CARLOS HANGARTER, Gaithersburg, MD (US); JONG YOON HA, Gaithersburg, MD (US)

(73) Assignee: NATIONAL INSTITUTE OF STANDARDS AND TECHNOLOGY, Gaithersburg, MD (US)

(21) Appl. No.: 13/623,789

(22) Filed: Sep. 20, 2012

Related U.S. Application Data
(60) Provisional application No. 61/537,192, filed on Sep. 21, 2011.

(51) Int. Cl. H01L 31/0224

(52) U.S. Cl. 136/256

(57) ABSTRACT

A thin film photovoltaic device with back contacts is disclosed. The thin film photovoltaic device may comprise 1) a first contact disposed in a first layer and having an upper surface and a lower surface; 2) a first semiconductor disposed in a second layer and having a lower surface disposed on the upper surface of the first contact; 3) an insulator or second semiconductor disposed in a third layer and on an upper surface of the first semiconductor; 4) a second contact disposed in a fourth layer and on the insulator or second semiconductor; and 5) an absorber disposed in a fifth layer and about the second contact. The absorber may comprise a p-type or a n-type semiconductor and the first semiconductor may comprise the other of the p-type and n-type semiconductor. The second contact may be patterned.

### CROSS-REFERENCE TO RELATED APPLICATIONS

This application claims the benefit under 35 U.S.C. §119(e) of U.S. Provisional Application No. 61/537,192, entitled ‘Substrate Geometry For Three Dimensional Photovoltaics Fabrication’, filed Sep. 21, 2011, which is hereby incorporated herein by reference in its entirety.

### STATEMENT REGARDING FEDERALLY SPONSORED RESEARCH OR DEVELOPMENT

This work is funded by the National Institute of Standards and Technology under the U.S. Department of Commerce.

### ATTORNEY DOCKET NUMBER: 11 023

Assignee: National Institute of Standards and Technology

### FIELD

Aspects of the present invention generally relate to photovoltaic devices and, more particularly, to photovoltaic devices having back contacts and methods of making same.

### BACKGROUND

Photovoltaic or solar devices may be used to convert light directly into electrical current. This conversion may be accomplished via the conjunction of n-type and p-type semiconducting materials that separate electron-hole pairs that are created when light is absorbed by the photovoltaic device.

Three generations of photovoltaic devices currently exist. First generation photovoltaic devices may have thicknesses in a range of from about one hundred (100) micrometers to hundreds (100s) of micrometers. First generation devices are generally thicker than subsequent generations because they may be based on silicon, and the indirect bandgap of silicon may require thicknesses within this range for obtaining a higher efficiency. For example, light might simply pass through the thinner silicon device instead of being absorbed by the silicon material.

Second generation devices may incorporate thin films of direct bandgap semiconducting materials. Such materials may include cadmium telluride or copper indium gallium diselenide for the p-type material. This p-type material may be classified as an absorber and may constitute the majority of the photovoltaic device. Lower costs may be possible using thin films, as compared to first generation devices, since thin film materials may be deposited using a variety of techniques and less material may be required to obtain a desired efficiency. However, decreased efficiency in light conversion may result when thin film devices are compared to crystalline silicon devices.

Third generation devices may include three-dimensional (3D) micro- or nano-scale structures (e.g., nano-wires and nano-rods in polymers) to improve their efficiency. Use of such third-generation devices is predicated on their having an even lower cost for conversion of solar energy than second generation devices and/or higher efficiency.

In connection with the development of second and third generation photovoltaic devices, various geometries are either being used or considered. Such geometries may include a geometry pursuant to which electrical contacts for extracting charge carriers (holes and electrons) are located on opposing surfaces of the thin film.

In some cases, third generation devices may contain nanoparticles that are dispersed during fabrication, as opposed to being grown on the substrate of the device itself. A drawback to this dispersed configuration may exist in that it may be a challenge to ensure uninterrupted connectivity of all constituent regions to an electrode. It may also be a challenge to connect the nanoparticles to the correct electrode.

Second and third generation geometries may have drawbacks in that the electrode on the side of the photovoltaic device that faces the sun may absorb or otherwise block some of the incoming light, thus adversely affecting the photovoltaic device's performance while also increasing its cost and processing complexity.

Advances have been made to address shortcomings associated with the blockage of incoming light caused by the front contacts (on the surface that faces the sun) in first generation devices. Devices that use interdigitated contacts on the back surface (surface not facing the sun) may eliminate light blockage caused by the front contacts. Silicon-based devices have been explored for more than thirty years. Such devices may use line or point contacts created through multiple lithographic patterning (masking) and deposition steps to create localized doping on the back surface of silicon wafers. The doped regions may connect to metal busbars and may also be located on the back surface for extraction of electrical current.

Sequential masking steps may also be used to create two interleaved arrays of n-type and p-type doped spots (point contacts) on the back surface of a silicon wafer, which may minimize recombination on the area that interfaces between metal and semiconductor. Such back surface interdigitated contacts on silicon wafers may be optimized by spacing the lines on which the doped regions fall. However, this process may be more difficult to implement on a large scale with thin film devices. For example, patterning the electrodes in a single lithographic pattern or layer may result in shorting of the electrodes.

There is a need for thin film photovoltaic devices that incorporate back contacts thereby reducing blockage of incoming light caused by front contacts.

### SUMMARY

According to one aspect of the present invention, a thin film photovoltaic device with back contacts is disclosed. The thin film photovoltaic device comprises; a first contact disposed in a first layer and having an upper surface and a lower surface; a first semiconductor disposed in a second layer and having a lower surface disposed on the upper surface of the first contact; a patterned insulator or a second semiconductor disposed in a third layer and on an upper surface of the first semiconductor; a second patterned contact disposed in a fourth layer and on the insulator or the second semiconductor; an absorber completely filling a fifth layer and disposed about the second contact; and the second layer being adjacent to the first layer, the third layer being adjacent the second layer, the fourth layer being adjacent the third layer, and the fifth layer being adjacent the fourth layer.

According to another aspect of the present invention, a thin film photovoltaic device with back contacts is disclosed. The thin film photovoltaic device comprises; a first electrode disposed in a first layer; a semiconductor disposed in a second layer on the first electrode; an insulator disposed in a third layer on the semiconductor and having an interrupted pattern; a second electrode disposed in a fourth layer and only on the insulator; and an absorber entirely filling a fifth layer and disposed on the second electrode and filling the interrupted patterns of the insulator and the second electrode.

According to yet another aspect, a thin film photovoltaic device with back contacts is disclosed. The thin film photovoltaic device comprises; a first contact; a first semiconductor disposed on the first contact; a second semiconductor disposed on the first semiconductor; an interrupted second contact disposed on the second semiconductor; and an absorber disposed on the second contact and filling the interrupts in the second contact.

### BRIEF DESCRIPTION OF THE DRAWINGS

FIG. 1 schematically shows a cross-sectional view of an aspect of a photovoltaic device of the present disclosure with back contacts;

FIGS. 2a and 2b show cross-sectional and plan views of a photovoltaic device of the present disclosure having three different semiconducting materials, each disposed in different layers with a layer comprised of a patterned contact between two such layers;

FIGS. 3a and 3b show cross-sectional and plan views of a photovoltaic device of the present disclosure having a patterned contact and a patterned insulator;

FIGS. 4a and 4b show cross-sectional and plan views of a photovoltaic device of the present disclosure having a patterned contact, an insulator, and an absorber extending into a semiconductor comprising layer;

FIGS. 5a and 5b show cross-sectional and plan views of a photovoltaic device of the present disclosure having a patterned contact and three different semiconducting materials, each disposed in a different layer, the patterned contact having a different geometry than that of the photovoltaic device shown in FIG. 2;

FIGS. 6a and 6b show cross-sectional and plan views of a photovoltaic device of the present disclosure having a superstrate geometry;

FIGS. 7a and 7b show cross-sectional and plan views of a photovoltaic device of the present disclosure having a patterned contact and a patterned insulator;

FIG. 8 shows a cross-sectional scanning electron microscope image of a photovoltaic device of the present disclosure;

FIG. 9 shows a cross-sectional scanning electron microscope image of another aspect of the photovoltaic device of the present disclosure; and

FIG. 10 is a graphical illustration of the External Quantum Efficiency (EQE) as a function of the energy of the incoming light (eV) for an aspect of the present disclosure.

### DETAILED DESCRIPTION

The following detailed description is of the currently contemplated modes of carrying out, or aspects of, the invention. The description is not to be taken in a limiting sense, but is made merely for the purpose of illustrating the general principles of the invention, since the scope of the invention is best defined by the appended claims. Various inventive features are described below that may each be used independently of one another or in combination with other features.

Aspects of the present disclosure may be of a first, second, or third generation device. For example, the photovoltaic device disclosed herein may be a third generation device and may include three-dimensional (3D) micro- or nano-scale structures (e.g., nano-wires and nano-rods in polymers), which may improve its efficiency. A third generation device may have a lower manufacturing cost than first and second generation devices and/or higher efficiency.

Aspects of the present disclosure may provide back-contact geometries for thin film devices with a micrometer-scale thickness and a contact (electrode) pitch that may be at or below a few micrometers. The pitch is defined as the imposed periodicity or typical pattern dimensions of the upper electrode.

In at least one aspect of the present disclosure, a photovoltaic device having two back contacts is provided wherein each back contact is disposed in a separate plane. In accordance with at least one aspect of the present disclosure, a three dimensionally structured thin film photovoltaic device is provided with back contacts in different layers. The back contacts may comprise two electrodes that are in different layers of the photovoltaic device wherein the layers having a contact are spaced apart with an insulating material or semiconducting material. The two electrodes may be configured to serve as back contacts for carrier extraction, when the device is in use. Optionally, the device may comprise an insulating substrate, or alternatively, one of the back contacts may be configured to dispose the other layers of the photovoltaic device and the device may be void of a substrate.

In at least one aspect of the present disclosure, a photovoltaic device comprises at least two electrodes with an insulating material therebetween. For example, a first electrode may be disposed in a first layer, an insulator may be disposed in a second layer, and a second electrode may be disposed in a third layer.

Aspects of the present disclosure may also comprise one or more thin film layers of one or more semiconducting materials or semiconductors. For example, the layer or layers between the first and second electrode may comprise one or more semiconducting material(s). The semiconducting materials may comprise n-type and/or p-type materials. Aspects of the presently disclosed device may further comprise one or more thin film layers of one or more absorbers. For example, an absorber may be disposed on the second electrode and the absorber may comprise a semiconducting material. In at least one aspect of the photovoltaic device disclosed herein, the semiconductor disposed on the first electrode comprises a first semiconductor and the absorber comprises a second semiconductor. The first semiconductor may comprise an n-type material and the second semiconductor may comprise a p-type material. Alternatively, the first semiconductor may comprise a p-type material and the second semiconductor may comprise a n-type material.

The present disclosure may provide a three-dimensional thin film photovoltaic device with back contacts that may be used for carrier collection when the device is illuminated. The back contacts may be disposed in different layers and may have an insulating material, or insulator, therebetween. Aspects, features and benefits may now become clear from a review of the following detailed description of illustrative aspects and the accompanying drawings.

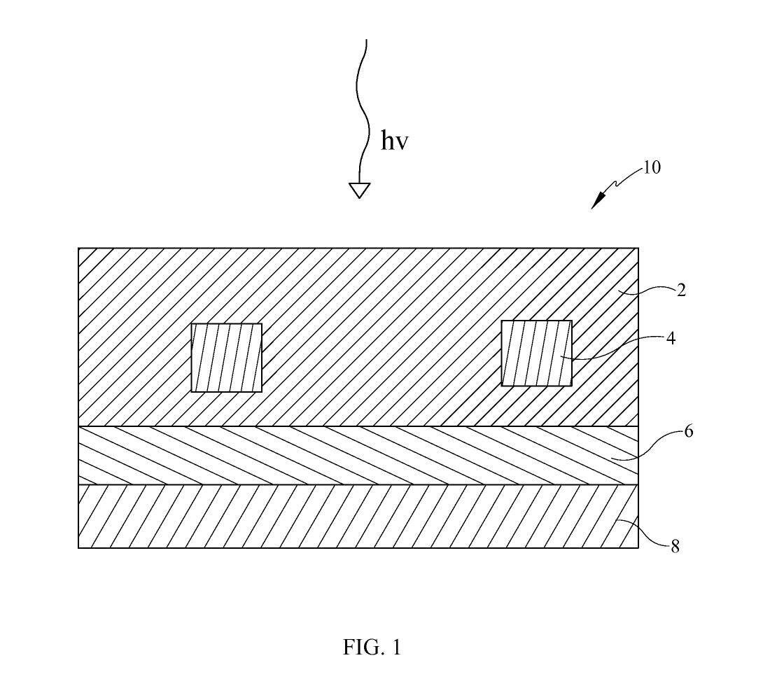

FIG. 1 shows photovoltaic device 10 with back contacts 8 and 4. Light, as represented by hv, is to illuminate absorber 2. Absorber 2 may fill a top outer most layer as shown in FIG. 1. Absorber 2 may comprise a p-type or n-type semiconducting material or semiconductor. For example, in at least one aspect of the present disclosure, absorber 2 may comprise, or consist of, a p-type semiconducting material such as cadmium telluride (CdTe), copper indium diselenide, copper indium gallium diselenide or copper oxide. In at least one other aspect of the present disclosure, absorber 2 may comprise, or consist of, a n-type semiconducting material such as cadmium sulfide (CdS) or zinc oxide. The p-type and/or n-type material may be doped or undoped.

A first back contact 8 may provide support, or serve as a substrate, for each other layer of photovoltaic device 10. A first semiconductor 6 may be disposed on first back contact 8. An absorber 2 may comprise a second semiconductor and may be disposed on first semiconductor 6. First semiconductor 6 may comprise a p-type semiconducting material or an n-type semiconducting material and absorber 2 may comprise the other of a p-type semiconducting material or n-type semiconducting material. Second contact 4 may be disposed in absorber 2. For example, second contact 4 may be surrounded or encased in absorber 2.

The absorber and first semiconductor may comprise different semiconducting materials providing a band gap. The absorber and/or semiconductor may comprise direct bandgap semiconducting materials such as amorphous silicon, cadmium telluride, copper-indium-diselenide or copper-indium-gallium-diselenide, copper oxide, tin selenide, and cadmium sulfide, for example.

The first contact or electrode 8 may be in the form of a continuous sheet and the second contact or electrode 4 may be patterned. For example, second contact 4 may comprise a sheet with an array of holes or may be in the form of wires, nano-wires, nano-rods, or an integrated damescene electrode. First and second electrodes 8 and 4 may comprise materials with large work functions such as gold, copper, molybdenum, or materials with small work functions such as indium tin oxide (ITO), titanium or aluminum, for example.

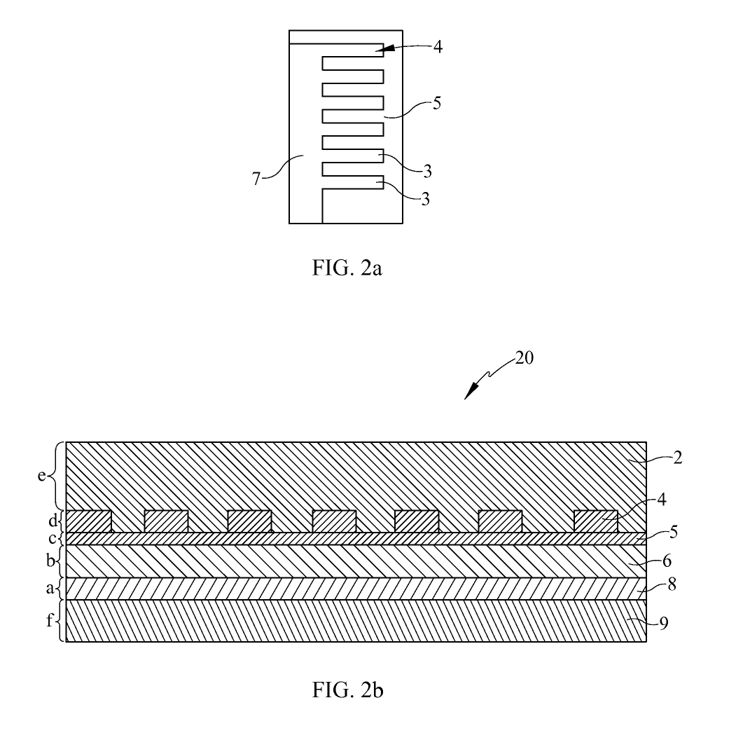

FIGS. 2a and 2b show photovoltaic device 20 with back contacts 4 and 8. FIG. 2b is a cross-sectional view of photovoltaic device 20 showing layers ‘a’-‘f’. Photovoltaic device 20 may be a thin film photovoltaic device and may comprise a first contact 8 disposed in a first layer ‘a’ and having an upper surface and a lower surface, as shown in FIG. 2b. A first semiconductor 6 may be disposed in a second layer ‘b’ and may have a lower surface disposed on the upper surface of the first contact 8. A second semiconductor 5 may be disposed in a third layer ‘c’ and on an upper surface of the first semiconductor 6. Second semiconductor 5 may comprise, or consist of, the same material as absorber 2, or may comprise, or consist of, different materials. In the aspect of the disclosure shown in FIGS. 2a and 2b, second semiconductor 5 is in the form of an uninterrupted sheet or layer, completely filling layer ‘c’.

A second contact 4 may be disposed in a fourth layer ‘d’ and on second semiconductor 5. An absorber 2 may be disposed in and completely fill a fifth layer ‘e’ and disposed about second semiconductor 5 and the second contact 4. Absorber 2 may comprise a semiconductor and may completely fill layer ‘e’. In at least one aspect of the present disclosure, absorber 2 comprises a p-type semiconducting material and first semiconductor 6 comprises a n-type semiconducting material. In at least one other aspect of the present disclosure, absorber 2 comprises a n-type semiconducting material and first semiconductor 6 comprises a p-type semiconducting material. In at least one additional aspect, absorber 2 comprises the same material as second semiconductor 5. Each layer may be deposited on the layer on which it is disposed.

Optionally, photovoltaic device 20 may comprise a substrate 9 in layer ‘f’. Substrate 9 may be configured and disposed to have first contact 8 disposed thereon and support layers ‘a’-‘e’. In at least one aspect of the present disclosure, photovoltaic device 20 is void of substrate 9 and first contact 8 may be configured and disposed to support layers ‘b’-‘e’, for example, first contact 8 may comprise a thick contact material. Second layer ‘b’ may be disposed on and/or adjacent to first layer ‘a’, the third layer ‘c’ may be disposed on and/or adjacent to second layer ‘b’, fourth layer ‘d’ may be disposed on and/or adjacent to third layer ‘c’, and fifth layer ‘e’ may be disposed on and/or adjacent to fourth layer ‘d’. In at least one aspect, photovoltaic device 20 has substrate 9 in layer ‘f’ and first layer ‘a’ may be dispose and/or adjacent with sixth layer ‘f’. Substrate 9 may be in the form of a thick contact or may comprise a material such as stainless steel or glass.

FIG. 2a shows a top view of photovoltaic device 20 having absorber 2 removed therefrom. In this respect, a portion of layer ‘d’ is shown having second contact 4 and a portion of layer ‘c’ is shown having second semiconductor 5. In this aspect, electrode or second contact 4 may comprise a group of parallel wires 3, which may be attached to each other by a contact pad 7, thus forming the second electrode or second contact 4. Second contact 4 and/or contact pad 7 may comprise micro- or nano-scale structures (e.g., nano-wires and nano-rods).

For purposes of the aspect or present disclosure shown in FIGS. 2a and 2b, pitch is the distance between the center of adjacent parallel wires 3. For purposes of the present disclosure, the pitch may range from tens of nanometers to tens of micrometers.

Absorber 2, of thin film photovoltaic device 20, may comprise a p-type semiconductor or a n-type conductor and first semiconductor 6 may comprise the other of the p-type semiconductor and n-type conductor. Second semiconductor 5, disposed in the third layer ‘c’, may be configured to provide electrical communication between first contact 8 and second contact 4, solely through first semiconductor 6 and second semiconductor 5.

Absorber 2 of thin film photovoltaic device 20 may comprise a p-type semiconductor and second semiconductor 5 may comprise the same or different p-type semiconductor. Alternatively, absorber 2 of thin film photovoltaic device 20 may comprise a n-type semiconductor and second semiconductor 5 may comprise the same or different n-type semiconductor. Second semiconductor 5 and absorber 2 may comprise at least one different material or they may comprise, or consist of, the same material.

The thin film photovoltaic device 20 may comprise a substrate 9 and first contact 8 may be disposed in first layer ‘a’ and have its lower surface disposed on substrate 9. Second contact 4 may have an interrupted pattern and thereby only partially filling fourth layer ‘d’ and absorber 2 may fill the interrupts in second contact 4.

Thin film photovoltaic device 20 may comprise first contact 8, first semiconductor 6 disposed on first contact 8, a second semiconductor 5 disposed on first semiconductor 6, an interrupted, or otherwise patterned, second contact 4 disposed on second semiconductor 5, and an absorber 2 disposed on second contact 5 and filling the interrupts or voids in the pattern in second contact 5. Absorber 2 may comprise a p-type semiconductor and second semiconductor 5 may comprise the same or different p-type semiconductor. Alternatively, absorber 2 may comprise a n-type semiconductor and second semiconductor 5 may comprise the same or different n-type semiconductor. Second semiconductor 5 and absorber 2 may comprise the same materials or different materials. In the aspect of the photovoltaic device shown in FIGS. 2a and 2b, second contact 4 comprises a plurality of interconnected wires 3, interrupted with spacing between the interconnected wires 3, and electrically interconnected with contact pad 7.

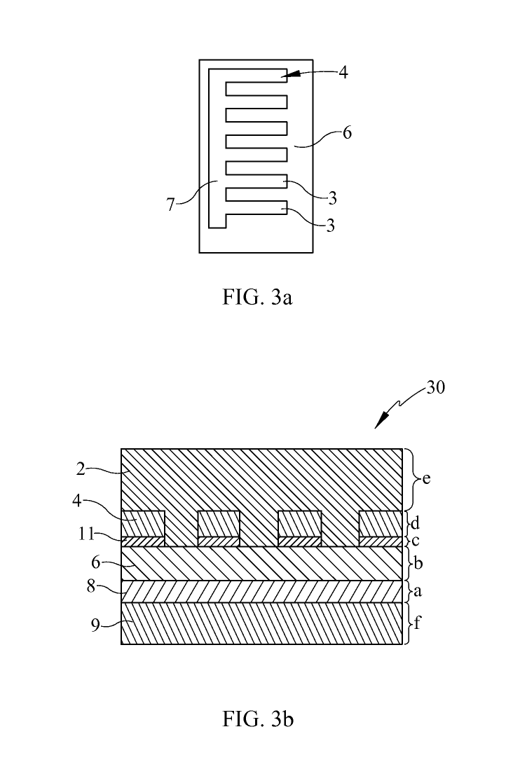

FIGS. 3a and 3b show photovoltaic device 30 with back contacts 4 and 8. FIG. 3b is a cross-sectional view of photovoltaic device 30 showing layers ‘a’-‘f’. Photovoltaic device 30 may be a thin film photovoltaic device and may comprise a first contact 8 disposed in a first layer ‘a’ and having an upper surface and a lower surface, as shown in FIG. 3b. A semiconductor 6 may be disposed in a second layer ‘b’ and have a lower surface disposed on the upper surface of the first contact 8. An insulator 11 may be disposed in a third layer ‘c’ and on an upper surface of the first semiconductor 6. Insulator 11 may comprise, or consist of, most any electrical insulating material such as Si0₂. Insulator 11 is configured and disposed to insulate electrical contact between semiconductor 6 and second contact 4. In this aspect of the disclosure, insulator 11 may be in a form or shape like, or corresponding with, second contact 4, partially filling layer ‘c’. However it is to be understood that the insulator 11 may have a variety of configurations which insulate contact 4 from semiconductor 6.

Second contact 4 may be disposed in a fourth layer ‘d’ and on insulator 11. Absorber 2 may comprise a second semiconductor and may be disposed in a fifth layer ‘e’ and about second contact 4, insulator 11, and semiconductor 6. Absorber 2 may be a semiconductor, for example a p-type or n-type semiconductor, and may completely fill layer ‘e’ and partially fill layers ‘c’ and ‘d’.

Optionally, photovoltaic device 30 may comprise a substrate 9 in layer ‘f’. Substrate 9 may be configured and disposed to have first contact 8 deposited thereon and support layers ‘a’-‘e’. In at least one aspect of the present disclosure, photovoltaic device 30 is void of substrate 9 and first contact 8 may be configured and disposed to support layers ‘b’-‘e’, for example contact 8 may comprise a thick contact material. Second layer ‘b’ may be deposited on, disposed on, and/or adjacent to first layer ‘a’, third layer ‘c’ may be deposited on, disposed on, and/or adjacent to second layer ‘b’, fourth layer ‘d’ may be deposited on, disposed on, and/or adjacent to third layer ‘c’, and fifth layer ‘e’ may be deposited on, disposed on, and/or adjacent to fourth layer ‘d’. In at least one aspect, photovoltaic device 30 has substrate 9 in layer ‘f’ and first layer ‘a’ may be deposited on, disposed on, and/or be adjacent with fifth layer ‘f’.

FIG. 3a shows a top view of photovoltaic device 30 having absorber 2 removed therefrom. In this respect, a portion of layer ‘d’ is shown having contact material 4 and a portion of layer ‘b’ is shown having semiconductor 6. In this aspect, electrode or contact material 4 may comprise a group of parallel wires 3, which may be attached to each other by a contact pad 7, thus forming the second electrode or contact 4.

Thin film photovoltaic device 30 with back contacts 8 and 4 comprises a first contact 8 disposed in first layer ‘a’ and has an upper surface and a lower surface. Semiconductor 6 is disposed in second layer ‘b’ and has a lower surface disposed on the upper surface of the first contact 8. An insulator 11 is disposed in a third layer ‘c’ and on an upper surface of the semiconductor 6. Second contact 4 is disposed in a fourth layer ‘d’ and on insulator 11. Absorber 2 completely fills fifth layer ‘e’ and is disposed about second contact 4 and insulator 11 within layers ‘c’ and ‘d’. Second layer ‘b’ may be adjacent first layer ‘a’, third layer ‘c’ may be adjacent second layer ‘b’, fourth layer ‘d’ may be adjacent third layer ‘c’, and fifth layer ‘e’ may be adjacent fourth layer ‘d’.

Absorber 2 of photovoltaic device 30 may comprise a p-type semiconductor or a n-type conductor and semiconductor 6 may comprise the other of the p-type semiconductor and n-type conductor. Insulator 11 may be disposed in third layer ‘c’. Insulator 11 may have most any form and may be configured to insulate direct electrical communication between semiconductor 6 and second contact 4 and ensure electrical communication between first contact 8 and second contact 4 solely through semiconductor 6 and absorber 2. Photovoltaic device 30 may comprise substrate 9 and first contact 8 may have its lower surface disposed on substrate 9. Second contact 4 may have an interrupted pattern and thereby only partially fill fourth layer ‘d’ and absorber 2 may fill the interrupts in second contact 4.

Photovoltaic device 30 may comprise a first electrode 8 disposed in first layer ‘a’, semiconductor 6 disposed in second layer ‘b’ on first electrode 8, insulator 11 may have an interrupted pattern and may be disposed in third layer ‘c’ on semiconductor 6, second electrode 4 may be disposed in fourth layer ‘d’ and only on insulator 11, absorber 2 may entirely fill fifth layer ‘e’ and be disposed on second electrode 4 and may fill the interrupted patterns of insulator 11 and second electrode 4. Insulator 11 may be comprised of a non-conducting or non-semiconducting materials. For example, insulator 11 may consist of SiO₂. Absorber 2 may comprise a p-type semiconductor or a n-type conductor and semiconductor 6 may comprise the other of the p-type semiconductor and n-type conductor. The p-type material may be selected from the group consisting of: cadmium telluride, copper indium diselenide, copper indium gallium diselenide and copper oxide. The p-type material may be doped or undoped. The n-type material may be either cadmium sulfide or zinc oxide, and may be doped or undoped.

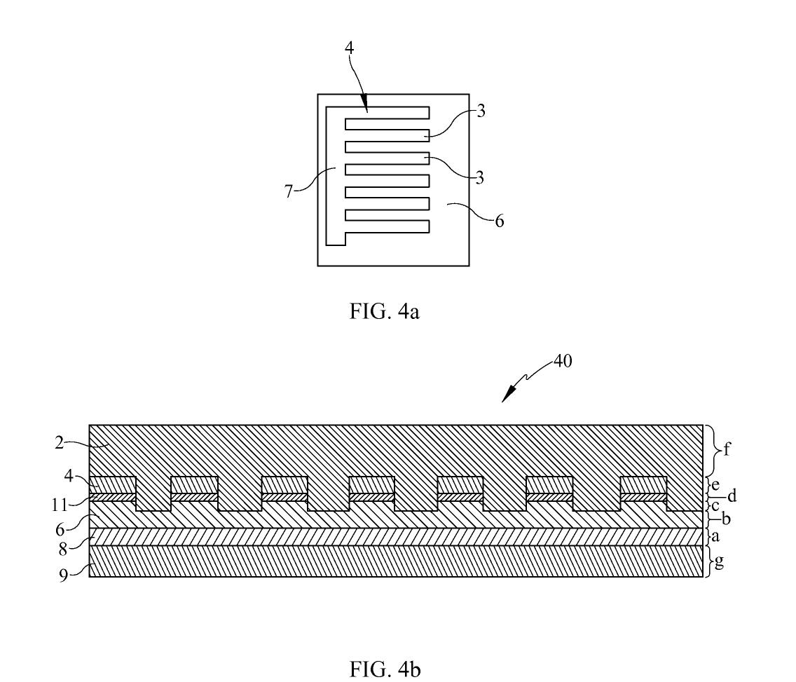

FIGS. 4a and 4b show photovoltaic device 40 with back contacts 4 and 8. FIG. 4b is a cross-sectional view of photovoltaic device 40 showing layers ‘a’-‘g’. Photovoltaic device 40 may be a thin film photovoltaic device and may comprise a first contact 8 disposed in a first layer ‘a’ and having an upper surface and a lower surface, as shown in FIG. 4b. A first semiconductor 6 may be disposed in a second layer ‘b’ and in a portion of third layer ‘c’, and have a lower surface disposed on the upper surface of the first contact 8. Insulator 11 may be disposed in a portion of fourth layer ‘d’ and on an upper surface of the first semiconductor 6. Insulator 11 may comprise, or consist of, a non-electrically conducting material. Second contact 4 may be disposed in a portion of a fifth layer ‘e’ and on insulator 11. Absorber 2 may comprise a semiconductor and may be disposed in a sixth layer ‘f’, and a portion of layers ‘c’, ‘d’, and ‘e’ and about second contact 4, insulator 11, and first semiconductor 6. Absorber 2 may be a semiconductor and may completely fill layer ‘f’.

Optionally, photovoltaic device 40 may comprise a substrate 9 in layer ‘g’. Substrate 9 may be configured and disposed to have first contact 8 deposited thereon and support layers ‘a’-‘f’. In at least one aspect of the present disclosure, photovoltaic device 40 is void of substrate 9 and first contact 8 may be configured and disposed to support layers ‘b’-‘f’, for example contact 8 may comprise a thick contact material. Second layer ‘b’ may be disposed on and/or adjacent to first layer ‘a’, the third layer ‘c’ may be disposed on and/or adjacent to second layer ‘b’, fourth layer ‘d’ may be disposed on and/or adjacent to third layer ‘c’, fifth layer ‘e’ may be disposed on and/or adjacent to fourth layer ‘d’, and sixth layer ‘f’ may be disposed on and/or adjacent to fifth layer ‘e’. In at least one aspect, photovoltaic device 40 has substrate 9 in layer ‘g’ upon which may dispose layer ‘a’.

FIG. 4a shows a top view of photovoltaic device 40 having absorber 2 removed therefrom. In this respect, a portion of layer ‘e’ is shown having contact material 4 and a portion of layer ‘b’ is shown having semiconductor 6. In this aspect shown in FIG. 4a, electrode or contact material 4 may comprise a group of wires 3, which may be attached to each other by a contact pad 7, thus forming the second electrode or contact 4. However, the presently disclosed photovoltaic device may have most any arrangement of contact 4. For example, contact 4 may be in the form of a grid of wires 3. The pitch of photovoltaic device 40 may be defined as the distance between centers of adjacent wires 3. For purposes of the present disclosure, the pitch may range from tens of nanometers to tens of micrometers. In the aspect of the photovoltaic device shown here, photovoltaic device 40, absorber 2 extends into semiconductor 6 and comprises a portion of layer ‘c’.

Thin film photovoltaic device 40 with back contacts 8 and 4 comprises a first contact 8 disposed in first layer ‘a’ and has an upper surface and a lower surface. Semiconductor 6 is disposed in second layer ‘b’ and a portion of third layer ‘c’ and has a lower surface disposed on the upper surface of the first contact 8. Insulator 11 is disposed in a fourth layer ‘d’ and on an upper surface of the semiconductor 6. Second contact 4 is disposed in a fifth layer ‘e’ and on insulator 11. Absorber 2 completely fills sixth layer ‘f’ and is disposed about second contact 4, insulator 11, and semiconductor 6. Second layer ‘b’ may be adjacent first layer ‘a’, third layer ‘c’ may be adjacent second layer ‘b’, fourth layer ‘d’ may be adjacent third layer ‘c’, fifth layer ‘e’ may be adjacent fourth layer ‘d’, and sixth layer ‘f’ may be adjacent fifth layer ‘e’.

Absorber 2 of photovoltaic device 40 may comprise a p-type semiconductor or a n-type conductor and semiconductor 6 may comprise the other of the p-type semiconductor and n-type conductor. Insulator 11 may be disposed in fourth layer ‘d’ and may be configured to insulate against direct electrical communication between semiconductor 6 and second contact 4 and ensure electrical communication between first contact 8 and second contact 4 solely through semiconductor 6 and absorber 2. Photovoltaic device 30 may comprise substrate 9 and first contact 8 may have its lower surface disposed on substrate 9. Second contact 4 may have an interrupted pattern and thereby only partially filling fifth layer ‘e’ and absorber 2 may fill the interrupts in second contact 4, interrupts in insulator 11, and a portion of layer ‘c’ comprising semiconductor material 6.

Photovoltaic device 40 may comprise a first electrode 8 disposed in first layer ‘a’, semiconductor 6 disposed in second layer ‘b’ on first electrode 8 and a portion of third layer ‘c’, insulator 11 may have an interrupted pattern and may be disposed in fourth layer ‘d’ on semiconductor 6, second electrode 4 may be disposed in fifth layer ‘e’ and only on insulator 11, absorber 2 may entirely fill sixth layer ‘f’ and be disposed on second electrode 4 and may fill the interrupted patterns of insulator 11 and second electrode 4 and may fill a portion of layer ‘c’. Insulator 11 may be comprised of a non-conducting and non-semiconducting materials. For example, insulator 11 may consist of SiO₂. Absorber 2 may comprise a p-type semiconductor or a n-type conductor and semiconductor 6 may comprise the other of the p-type semiconductor and n-type conductor.

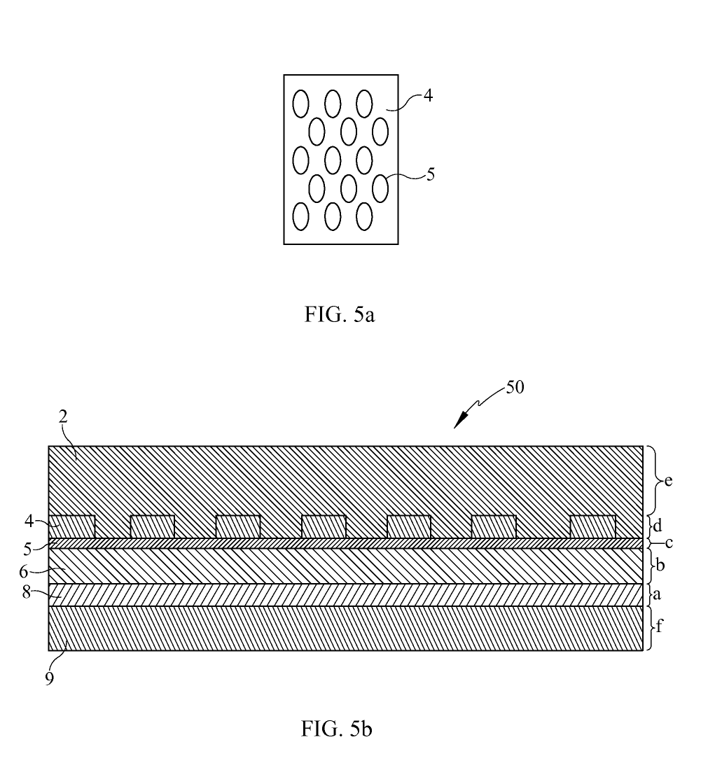

FIGS. 5a and 5b show photovoltaic device 50 with back contacts 4 and 8. FIG. 5b is a cross-sectional view of photovoltaic device 50 showing layers ‘a’-‘f’. Photovoltaic device 50 may be a thin film photovoltaic device and may comprise a first contact 8 disposed in a first layer ‘a’ and having an upper surface and a lower surface, as shown in FIG. 5b. A first semiconductor 6 may be disposed in a second layer ‘b’ and have a lower surface disposed on the upper surface of the first contact 8. Second semiconductor 5 may be disposed in third layer ‘c’ and on an upper surface of the first semiconductor 6. Second semiconductor 5 may comprise, or consist of, the same material as absorber 2, or may comprise, or consist of, different material. In at least one aspect of device 50, absorber 2 comprises a p-type semiconducting material and second semiconductor 5 comprises a different p-type semiconducting material. In at least one other aspect of device 50, absorber 2 comprises a n-type semiconducting material and second semiconductor 5 comprises a different n-type semiconducting material. In at least one additional aspect of device 50, absorber 2 and second semiconductor 5 comprise the same material. Second contact 4 may be disposed in a portion of a fourth layer ‘d’ and on semiconductor 5. Second contact 4 may be in the form of a perforated sheet or sheet having an array of holes, as shown in FIG. 5b. Absorber 2 may comprise a second semiconductor and may be disposed in a fifth layer ‘e’ and a portion of layer ‘d’ and about second contact 4 and second semiconductor 5. Absorber 2 may be a semiconductor and may completely fill layer ‘e’ and the array of holes in second contact 4.

Optionally, photovoltaic device 50 may comprise a substrate 9 in layer ‘f’. Substrate 9 may be configured and disposed to have first contact 8 disposed and/or deposited thereon and support layers ‘a’-‘e’. In at least one aspect of the present disclosure, photovoltaic device 50 is void of substrate 9 and first contact 8 may be configured and disposed to support layers ‘b’-‘e’, for example contact 8 may comprise a thick contact material. Second layer ‘b’ may be disposed on and/or adjacent to first layer ‘a’, the third layer ‘c’ may be disposed on and/or adjacent to second layer ‘b’, fourth layer ‘d’ may be disposed on and/or adjacent to third layer ‘c’, and fifth layer ‘e’ may be disposed on and/or adjacent to fourth layer ‘d’.

FIG. 5a shows a top view of photovoltaic device 50 having absorber 2 removed therefrom. In this respect, a portion of layer ‘d’ is shown having contact material 4 and a portion of layer ‘c’ is shown having second semiconductor 5. In this aspect, electrode or contact material 4 may comprise a perforated sheet or a sheet with an array of holes, thus forming the second electrode or contact 4. The array of holes may be a regular array, as shown, or an irregular array. However, it is to be understood that the presently disclosed photovoltaic device may have most any configuration of contact material 4. A pitch of photovoltaic device 50 may range from tens of nanometers to tens of micrometers.

Absorber 2, of thin film photovoltaic device 50, may comprise a p-type semiconductor or a n-type conductor and first semiconductor 6 may comprise the other of the p-type semiconductor and n-type conductor. Second semiconductor 5, disposed in the third layer ‘c’, may be configured to provide electrical communication between first contact 8 and second contact 4 solely through first semiconductor 6 and second semiconductor 5.

Absorber 2 of thin film photovoltaic device 50 may comprise a p-type semiconductor and second semiconductor 5 may comprise the same or different p-type semiconductor. Alternatively, absorber 2 of thin film photovoltaic device 20 may comprise a n-type semiconductor and second semiconductor 5 may comprise the same or different n-type semiconductor. Second semiconductor 5 and absorber 2 may comprise at least one different material or they may comprise, or consist of, the same material.

The thin film photovoltaic device 50 may comprise a substrate 9 and first contact 8 may be disposed in first layer ‘a’ and have its lower surface disposed on substrate 9. Second contact 4 may have an interrupted pattern and thereby only partially filling fourth layer ‘d’ and absorber 2 may fill the interrupts in second contact 4.

Thin film photovoltaic device 50 may comprise first contact 8, first semiconductor 6 disposed on first contact 8, a second semiconductor 5 disposed on first semiconductor 6, an interrupted second contact 4 disposed on second semiconductor 5, and an absorber 2 disposed on second contact 4 and filling the interrupts in second contact 4. Absorber 2 may comprise a p-type semiconductor and second semiconductor 5 may comprise the same or different p-type semiconductor. Alternatively, absorber 2 may comprise a n-type semiconductor and second semiconductor 5 may comprise the same or different n-type semiconductor. Second semiconductor 5 and absorber 2 may comprise the same materials or different materials. In the aspect of the photovoltaic device shown in FIGS. 5a and 5b, second contact 4 comprises an interrupted sheet or a sheet with an array of holes.

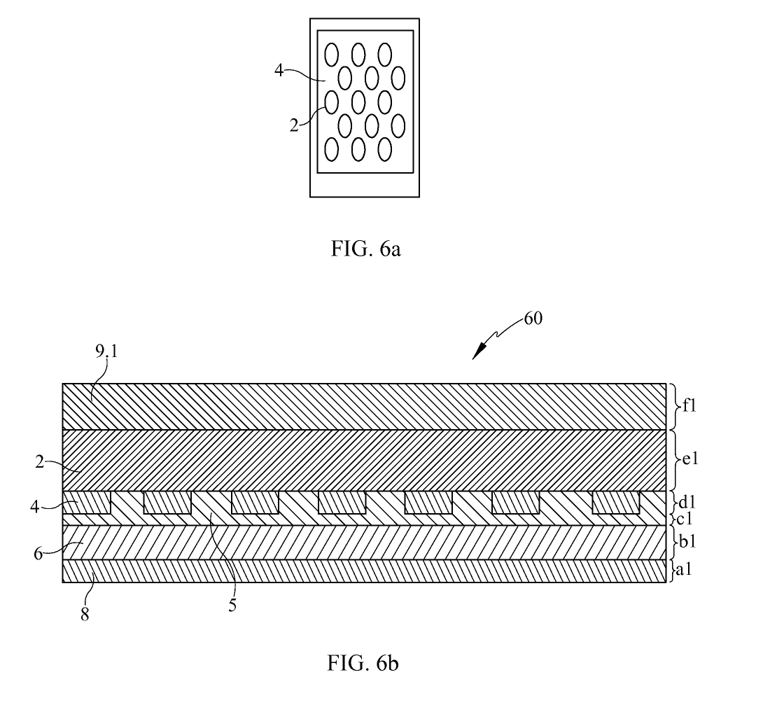

FIGS. 6a and 6b show photovoltaic device 60 with back contacts 4 and 8 and having a superstrate geometry. FIG. 6b is a cross-sectional view of photovoltaic device 60 showing layers ‘a1’-‘f1’. Photovoltaic device 60 may be a thin film photovoltaic device and may comprise a superstrate 9.1 disposed in a layer ‘f1’ and having an upper surface and a lower surface, as shown in FIG. 6b. In this aspect, superstrate 9.1 may comprise a transparent superstrate. Absorber 2 may be disposed in a second layer ‘e1’ and have an upper surface disposed on the lower surface of superstrate 9.1. First contact 4, comprising a first contact material, may be disposed in a portion of third layer ‘d1’ and have an upper surface disposed on the lower surface of absorber 2. First semiconductor 5 may be disposed in a portion of third layer ‘d1’ and on a portion of the lower surface of absorber 2 and about first contact 4. In this respect, layer ‘d1’ may comprise a portion of first semiconductor 5 and layer ‘c1’ may be solely comprised of first semiconductor 5. First semiconductor 5 may comprise, or consist of, the same material as absorber 2, or may comprise, or consist of, different materials. For example, absorber 2 may comprise a p-type semiconducting material and first semiconductor 5 may comprise a different p-type semiconducting material. Second semiconductor 6 may be disposed in a fifth layer ‘b1’ and have an upper surface disposed on the lower surface of first semiconductor 5. In at least one aspect of the present disclosure, first semiconductor 5 and absorber 2 may comprise the same or different n-type semiconductor and second semiconductor 6 may comprise a p-type semiconductor. In at least one other aspect of the present disclosure, first semiconductor 5 and absorber 2 may comprise the same or different p-type semiconductor and second semiconductor 6 may comprise a n-type semiconductor. Second contact 8 may be disposed in a sixth layer ‘a1’ and have an upper surface disposed on the lower surface of second semiconductor 6.

Second layer ‘e1’ may be deposited on, disposed on, and/or adjacent to first layer ‘f1’, third layer ‘d1’ may be deposited on, disposed on, and/or adjacent to second layer ‘e1’, fourth layer ‘c1’ may be deposited on, disposed on, and/or adjacent to third layer ‘d1’, fifth layer ‘b1’ may be deposited on, disposed on, and/or adjacent to fourth layer ‘c1’, and sixth layer ‘a1’ may be deposited on, disposed on, and/or adjacent to fifth layer ‘b1’.

FIG. 6a shows a bottom view of photovoltaic device 60 having the second contact material 8, second semiconductor 6, and first semiconductor 5 removed therefrom. In this respect, a portion of layer ‘d1’ is shown having first contact material 4 and a portion of layer ‘e1’ is shown having absorber 2. In this aspect, electrode or contact material 4 may comprise a perforated sheet, a sheet with substantially equal spaced holes, or a sheet with an irregular array of holes therein. The pitch may range from tens of nanometers to tens of micrometers.

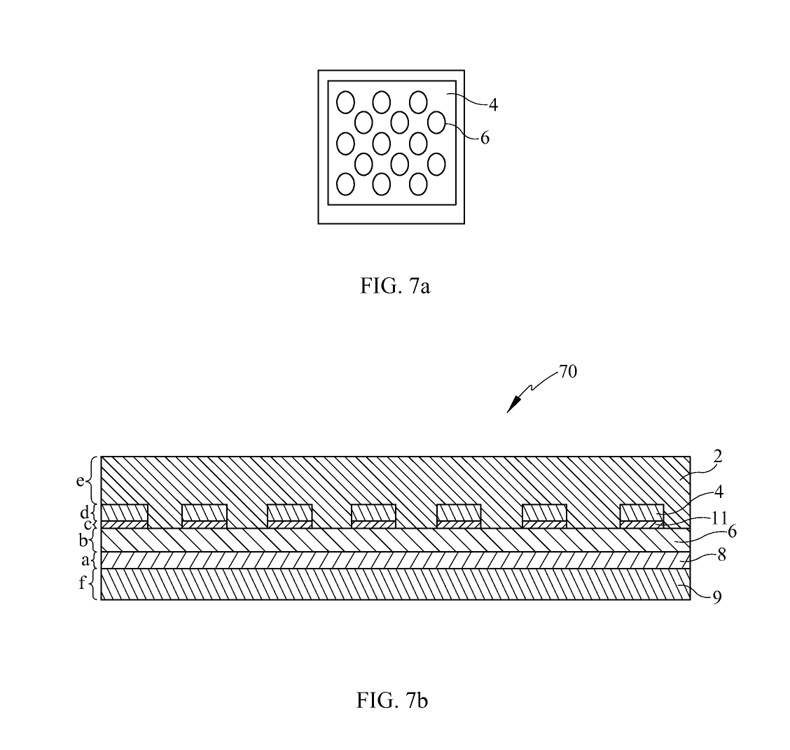

FIGS. 7a and 7b show photovoltaic device 70 with back contacts 4 and 8. FIG. 7b is a cross-sectional view of photovoltaic device 70 showing layers ‘a’-‘f’. Photovoltaic device 70 may be a thin film photovoltaic device and may comprise a first contact 8 disposed in a first layer ‘a’ and having an upper surface and a lower surface, as shown in FIG. 7b. A first semiconductor 6 may be disposed in a second layer ‘b’ and have a lower surface disposed on the upper surface of the first contact 8. An insulator 11 may be disposed in a third layer ‘c’ and on an upper surface of the semiconductor 6. Insulator 11 may comprise one or more electrically insulating materials. Insulator 11 is configured and disposed to insulate against electrical contact between second contact 4 and semiconductor 6. Therefore, electrical communication between first and second contacts 8 and 4 is solely through semiconductor 6 and absorber 2. In this aspect of the disclosure, insulator 11 may be in a form or shape like, or similar to, second contact 4, partially filling layer ‘c’. However it is to be understood that the insulator 11 may have a variety of configurations which insulate contact 4 from semiconductor 6.

Second contact 4 may be disposed in a fourth layer ‘d’ and on insulator 11. Absorber 2 may comprise a semiconductor and may be disposed in a fifth layer ‘e’ and about second contact 4, insulator 11, and first semiconductor 6. Absorber 2 may be a semiconductor and may completely fill layer ‘e’ and partially fill layers ‘c’ and ‘d’.

Optionally, photovoltaic device 70 may comprise a substrate 9 in layer ‘f’. Substrate 9 may be configured and disposed to have first contact 8 deposited, or otherwise disposed, thereon and support layers ‘a’-‘e’. In at least one aspect of the present disclosure, photovoltaic device 70 is void of substrate 9 and first contact 8 may be configured and disposed to support layers ‘b’-‘e’, for example contact 8 may comprise a thick contact material. Second layer ‘b’ may be disposed on and/or adjacent to first layer ‘a’, the third layer ‘c’ may be disposed on and/or adjacent to second layer ‘b’, fourth layer ‘d’ may be disposed on and/or adjacent to third layer ‘c’, and fifth layer ‘e’ may be disposed on and/or adjacent to fourth layer ‘d’. In at least one aspect, photovoltaic device 70 has substrate 9 in layer ‘f’ and fifth layer ‘e’ may dispose and/or be adjacent with fourth layer ‘d’. Each layer may be deposited on an adjacent layer. For example, contact 8 may be deposited substrate 9, semiconductor 6 may be deposited on contact 8, insulator 11 may be deposited on semiconductor 6, contact 4 may be deposited on insulator 11, and absorber 2 may be deposited on contact 4.

FIG. 7a shows a top view of photovoltaic device 70 having absorber 2 removed therefrom. In this respect, a portion of layer ‘d’ is shown having contact material 4 and a portion of layer ‘b’ is shown having first semiconductor 6. In this aspect, electrode or contact material 4 may comprise an array of holes in a sheet, forming the second electrode or contact 4, and insulator 11 may be similarly shaped.

Thin film photovoltaic device 70 with back contacts 8 and 4 comprises a first contact 8 disposed in first layer ‘a’ and has an upper surface and a lower surface. Semiconductor 6 is disposed in second layer ‘b’ and has a lower surface disposed on the upper surface of the first contact 8. An insulator 11 is disposed in a third layer ‘c’ and on an upper surface of the semiconductor 6. Second contact 4 is disposed in a fourth layer ‘d’ and solely on insulator 11. Absorber 2 completely fills fifth layer ‘e’ and is disposed about second contact 4 and insulator 11. Second layer ‘b’ may be adjacent first layer ‘a’, third layer ‘c’ may be adjacent second layer ‘b’, fourth layer ‘d’ may be adjacent third layer ‘c’, and fifth layer ‘e’ may be adjacent fourth layer ‘d’.

Absorber 2 of photovoltaic device 70 may comprise a p-type semiconductor or a n-type conductor and semiconductor 6 may comprise the other of the p-type semiconductor and n-type conductor. Insulator 11 may be disposed in third layer ‘c’ and may be configured to insulate against direct electrical communication between semiconductor 6 and second contact 4 and ensure electrical communication between first contact 8 and second contact 4 occurs solely through semiconductor 6 and absorber 2. Photovoltaic device 70 may comprise substrate 9 and first contact 8 may be have its lower surface disposed on substrate 9. Second contact 4 may have an interrupted pattern and thereby only partially filling fourth layer ‘d’ and absorber 2 may fill the interrupts in second contact 4.

Photovoltaic device 70 may comprise a first electrode 8 disposed in first layer ‘a’, semiconductor 6 disposed in second layer ‘b’ on first electrode 8, insulator 11 may have an interrupted pattern and may be disposed in third layer ‘c’ on semiconductor 6, second electrode 4 may be disposed in fourth layer ‘d’ and only on insulator 11, absorber 2 may entirely fill fifth layer ‘e’ and be disposed on second electrode 4 and may fill the interrupted patterns of insulator 11 and second electrode 4. Insulator 11 may be comprised of a non-conducting or non-semiconducting materials. For example, insulator 11 may consist of SiO₂. Absorber 2 may comprise a p-type semiconductor or a n-type conductor and semiconductor 6 may comprise the other of the p-type semiconductor and n-type conductor. The p-type material may be selected from the group consisting of: cadmium telluride, copper indium diselenide, copper indium gallium diselenide and copper oxide. The p-type material may be doped or undoped. The n-type material may be either cadmium sulfide or zinc oxide, and may be doped or undoped.

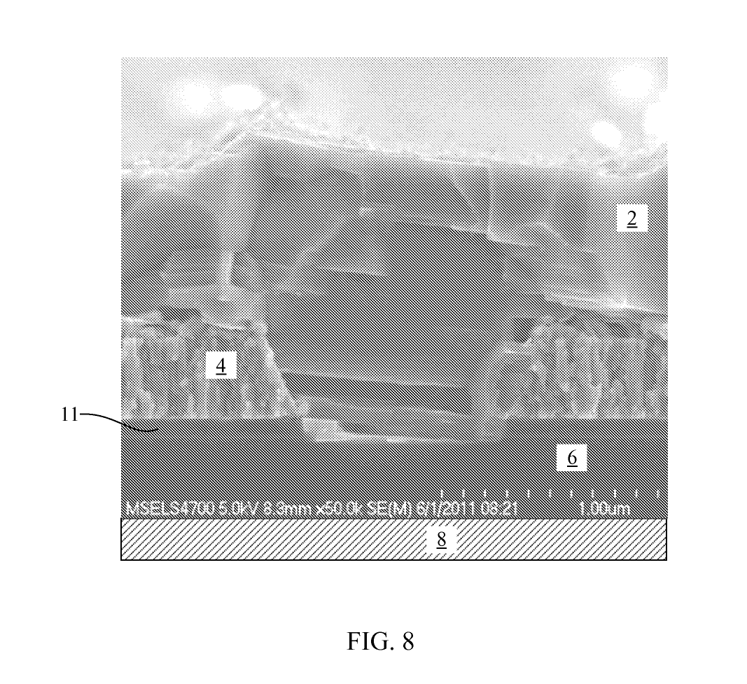

FIG. 8 shows a scanning electron microscope image of a cross-section of a photovoltaic device of the present disclosure. For example, the aspect of the present disclosure may have a configuration similar to photovoltaic devices 40 or 70. Semiconductor 6 is disposed on an upper surface of a first contact 8, not shown. Insulator 11 is disposed on an upper surface of semiconductor 6. Second contact 4 is disposed on insulator 11. Absorber 2 surrounds or encases contact 4, insulator 11, and semiconductor 6.

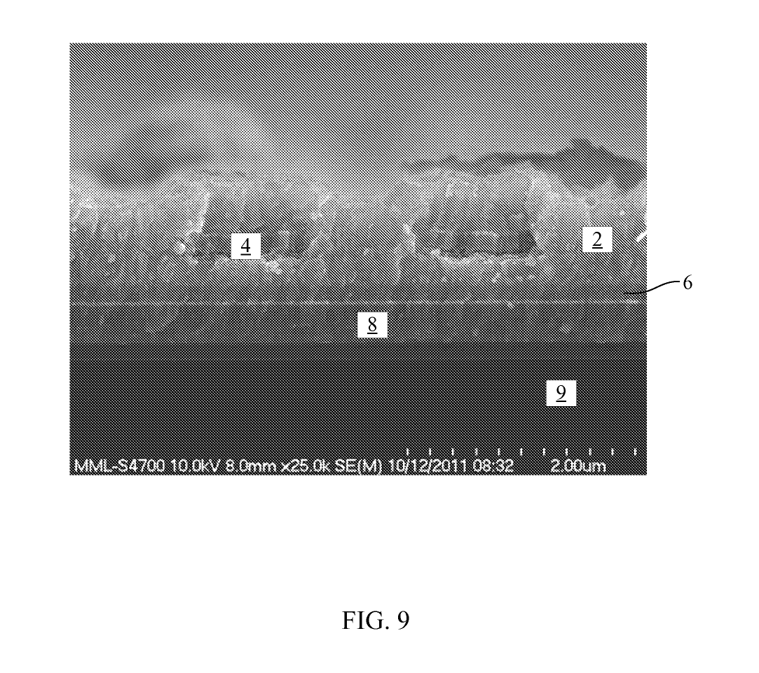

FIG. 9 shows a scanning electron microscope image of a cross-section of a photovoltaic device of the present disclosure. For example, the aspect of the present disclosure may show a configuration similar to photovoltaic device 10. First contact 8 is shown disposed on an upper surface of substrate 9. Semiconductor 6 is disposed on an upper surface of the first contact 8. Absorber 2 is disposed on an upper surface of semiconductor 6. Second contact 4 is disposed on a portion of absorber 2 and absorber 2 surrounds or encases contact 4 and semiconductor 6. Electrical communication between first contact 8 and second contact 4 is solely through absorber 2 and semiconductor 6.

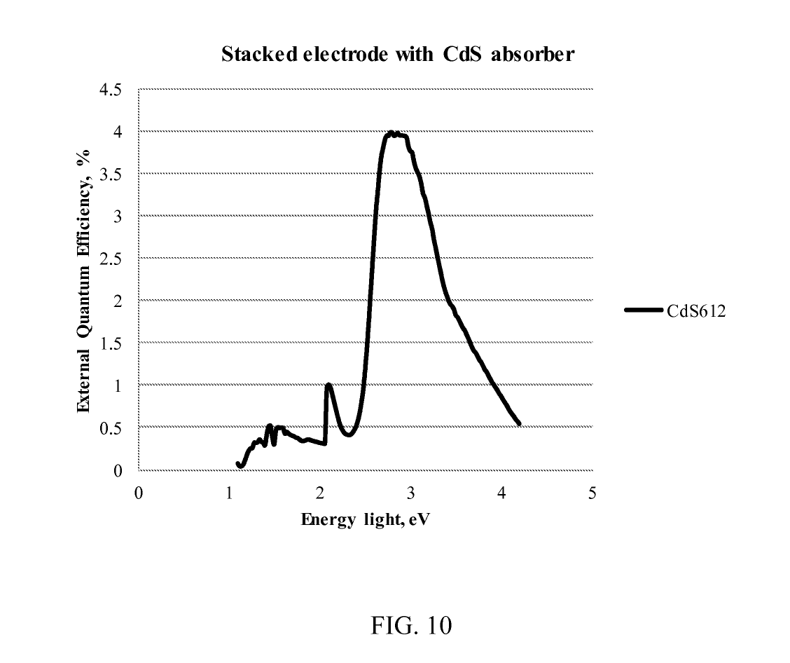

FIG. 10 shows a plot of External Quantum Efficiency, specifically the % of light converted and captured as electrical current across the contacts 4 and 8, versus the energy of the light photons impinging on the CdS absorber 2 of the device, the light energy measured in electron volts eV, for an aspect of the present disclosure having an absorber comprising CdS. The transition from zero to nonzero fraction of light converted into electrical current at energies greater than ˜2.4 eV is an unambiguous signature of light absorbed in the CdS absorber as the CdS bandgap is approximately this value. Aspects of the present disclosure may be made by depositing a bottom electrode in planar form, for example by thin film deposition processes. The electrode may be deposited on a substrate. A semiconductor may then be deposited on the electrode. An insulator, second semiconductor, or first amount of an absorber may then be deposited on the semiconductor. A second electrode may then be deposited on the insulator, second semiconductor, or first amount of an absorber. An absorber, or second amount thereof, may then be deposited on the second electrode. The second electrode may be interrupted or otherwise not completely filling its layer. For example, the second electrode may be in the form of a plurality of wires or may have holes. In this aspect, the absorber, or second amount thereof, fills the interruptions in the second electrode and completely covers the electrode, forming an outer layer that is solely comprised of the absorber. The use of an interrupted, or embedded patterned electrode, may eliminate upper surface contacts and allow full illumination of most of the absorber.

Aspects of the present disclosure may be made by depositing a bottom conductor or using a conducting substrate. A first amount of a semiconducting material may be deposited on the bottom conductor. A different semiconducting material may then be deposited on the first amount of semiconducting material. A second electrode may be patterned and deposited on the semiconducting materials. The absorber may then be deposited to fill the pattern and cover the second electrode. Deposition may by any process as is known in the art. For example, a thin film deposition process such as sputtering, chemical vapor deposition (CVD), chemical bath, sol-gel, ink, may be used to deposit one or more layers. One or more deposited thin film layers may be formed by at least one of electrodeposition, chemical vapor deposition, chemical bath deposition, sputtering, physical vapor deposition, evaporation, spray coating, spin coating, dip coating, flow coating, ink jetting, plasma spraying, and laser ablation. For superstrate geometry, as shown in FIGS. 6a and 6b, the bulk of the absorber may be annealed prior to deposition of any other material including the embedded electrode.

In at least one aspect of the present disclosure, a photovoltaic device having a substrate geometry may be made by: 1) depositing planar rear electrode (ITO, metal); 2) depositing planar n-type (or p-type) semiconductor, e.g., CdS; 3) depositing planar p-type (or n-type) semiconductor, e.g., CdTe; 4) patterning and depositing front electrode; and 4) depositing and blanketing majority of p-type (or n-type) semiconductor with an ‘absorber’, e.g., CdTe. An aspect of the present disclosure having a superstrate geometry may be made by following the above steps 1)-4) in reverse order.

Properties of the presently disclosed photovoltaic device may be dependent on the geometry of one or more layers. Therefore, lithography may be used to control the geometry of one or more layers. A nonplanar surface topography of one or more layers, the outer layer of the absorber for example, may improve efficiency. The performance of the photovoltaic device of the present disclosure may not be restricted by transparency and conductivity tradeoffs, as with conducting transparent oxides (CTO) and window layers, since there may be no CTO layer in the presently disclosed photovoltaic device. Aspects of the present disclosure may not require precise or high quality lithography since the electrodes are in different layers separated by at least one semiconductor layer, avoiding the shorting of adjacent +/− electrodes. This may permit inexpensive, lower quality patterning of layers that may be patterned.

While the specification describes particular embodiments and/or aspects of the present invention, those of ordinary skill may devise variations of the present invention without departing from the scope of the claims herein.

1. A thin film photovoltaic device with back contacts comprising:
a first contact disposed in a first layer and having an upper surface and a lower surface;
a first semiconductor disposed in a second layer and having a lower surface disposed on the upper surface of the first contact;
a patterned insulator or a second semiconductor disposed in a third layer and on an upper surface of the first semiconductor;
a patterned second contact disposed in a fourth layer and on said insulator or said second semiconductor;
an absorber completely filling a fifth layer and disposed about the second contact; and
the second layer being adjacent the first layer, the third layer being adjacent the second layer, the fourth layer being adjacent the third layer, and the fifth layer being adjacent the fourth layer.

2. The thin film photovoltaic device of claim 1 wherein said absorber comprises a p-type semiconductor or a n-type semiconductor and said first semiconductor comprises the other of the p-type semiconductor and n-type semiconductor.

3. The thin film photovoltaic device of claim 1 wherein said insulator is disposed in the third layer and said insulator is configured to insulate against direct electrical communication between said first semiconductor and said second contact and ensure electrical communication between said first contact and said second contact occurs solely through said first semiconductor and said absorber.

4. The thin film photovoltaic device of claim 1 wherein said second semiconductor is disposed in the third layer and is configured to provide electrical communication between said first contact and said second contact solely through first semiconductor and said second semiconductor.

5. The thin film photovoltaic device of claim 4 comprising the limitations of a) or b):
a) wherein said absorber comprises a p-type semiconductor and said second semiconductor comprises the same or different p-type semiconductor; and
b) wherein said absorber comprises a n-type semiconductor and said second semiconductor comprises the same or different n-type semiconductor.

6. The thin film photovoltaic device of claim 4 wherein said second semiconductor and said absorber comprise at least one different material.

7. The thin film photovoltaic device of claim 4 wherein said second semiconductor and said absorber comprise the same material.

8. The thin film photovoltaic device of claim 1 further comprising a substrate and said first contact disposed in the first layer has its lower surface disposed on said substrate.

9. The thin film photovoltaic device of claim 1 wherein said absorber fills the interrupts in said second contact.

10. A thin film photovoltaic device with back contacts comprising:
a first electrode disposed in a first layer;
a semiconductor disposed in a second layer on said first electrode;
a patterned insulator disposed in a third layer on said semiconductor and having an interrupted pattern;
a patterned second electrode disposed in a fourth layer and only on said insulator; and
an absorber entirely filling a fifth layer and disposed on said second electrode and filling the interrupted patterns of said insulator and said second electrode.

11. The thin film photovoltaic device with back contacts of claim 10 wherein said insulator is comprised of non-semiconducting materials.

12. The thin film photovoltaic device of claim 10 wherein said absorber comprises a p-type semiconductor or a n-type conductor and said semiconductor comprises the other of the p-type semiconductor and n-type conductor.

13. The thin film photovoltaic device of claim 12 wherein said p-type material is selected from the group consisting of: cadmium telluride, copper indium diselenide, copper indium gallium diselenide and copper oxide, and wherein the p-type material is doped or undoped.

14. The thin film photovoltaic device of claim 12 wherein said n-type material is either cadmium sulfide or zinc oxide, and wherein the n-type material is doped or undoped.

15. A back contact thin film photovoltaic device comprising:
a first contact;
a first semiconductor disposed on said first contact;
a second semiconductor disposed on said first semiconductor;
an interrupted second contact disposed on said second semiconductor; and
an absorber disposed on said second contact and filling the interrupts in said second contact.

16. The thin film photovoltaic device of claim 15 wherein said absorber comprises a p-type semiconductor or a n-type conductor and said first semiconductor comprises the other of the p-type semiconductor and n-type conductor.

17. The thin film photovoltaic device of claim 15 comprising the limitations of a) or b):
a) wherein said absorber comprises a p-type semiconductor and said second semiconductor comprises the same or different p-type semiconductor; and
b) wherein said absorber comprises a n-type semiconductor and said second semiconductor comprises the same or different n-type semiconductor.

18. The back contact thin film photovoltaic device of claim 17 wherein said second semiconductor and said absorber comprise the same material.

19. The back contact thin film photovoltaic device of claim 15 wherein said second contact comprises a planar sheet interrupted with holes therein.

20. The back contact thin film photovoltaic device of claim 15 wherein said second contact comprises a plurality of interconnected wires interrupted with spacing between the interconnected wires.
